(19) United States
(12) Patent Application Publication
(10) Pub. No.: US 2019/0223300 A1
(43) Pub. Date: Jul. 18, 2019

(54) EMBEDDED FLEXIBLE CIRCUIT BOARD AND METHOD FOR MANUFACTURING THE SAME

(71) Applicants: Avary Holding (Shenzhen) Co., Limited., Shenzhen (CN); HongQiSheng Precision Electronic (QinHuangDao) Co., Ltd., Qinhuangdao (CN)

(72) Inventors: LI-KUN LIU, Shenzhen (CN); YAN-LU LI, Shenzhen (CN); YANG LI, Shenzhen (CN)

(21) Appl. No.: 16/051,089

(22) Filed: Jul. 31, 2018

(30) Foreign Application Priority Data
Jan. 16, 2018 (CN) 201810041301.7

(51) Int. Cl. H05K 3/46; H05K 3/32; H05K 1/11; H05K 1/18

(52) U.S. Cl. CPC H05K 3/4679; H05K 3/323; H05K 1/111; H05K 3/328; H05K 1/186; H05K 1/189; H05K 3/467; H05K 1/188

(57) ABSTRACT

A method of manufacturing an embedded flexible circuit board includes: providing a first circuit substrate comprising at least one welding pad; providing at least one embedded middle body including a base a thin-film resistor formed onto the base, and a conducting resin, the conducting resin formed onto the thin-film resistor and being opposite from the base; fitting the embedded middle body onto the at least one welding pad through the conducting resin, and electronically connecting the thin-film resistor and the at least one welding pad through the conducting resin; removing the base; and forming a second circuit substrate at a side of the first circuit substrate where the thin-film resistor attached on, thereby the thin-film resistor sandwiched between the first circuit substrate and the second circuit substrate. An embedded flexible circuit board made by the method is also provided.

### FIELD

The subject matter herein generally relates to flexible circuit boards, and particularly relates to an embedded flexible circuit board and its manufacture.

### BACKGROUND

Electronic elements (such as resistance, capacitance, and so on) of a flexible printed circuit board are embedded into the flexible printed circuit board, so that a thickness of the flexible printed circuit board is reduced, as well as reducing a thickness of a electronic product having the flexible printed circuit board. In traditional manufacturing process, a multilayer circuit board with an open hole defined thereon is formed by a build-up method on a circuit substrate, and the electronic elements are received in the open-hole. The open hole is defined after forming the multilayer circuit board or during forming the multilayer circuit board. However, it is difficult to manufacture the open-hole, and there is a problem that the open hole fitting may be inaccurate, resulting in lower yield of the flexible printed circuit board and increased production costs.

Therefore, there is room for improvement within the art.

### BRIEF DESCRIPTION OF THE DRAWINGS

Implementations of the present technology will now be described, by way of only, with reference to the attached figures.

FIG. 1 shows a flowchart of a method for manufacturing an embedded flexible circuit board according to an embodiment.

FIG. 2 shows a cross sectional view of a first circuit substrate used in the method of manufacturing the embedded flexible circuit board of FIG. 1.

FIG. 3 shows a cross sectional view of an embedded middle body used in the method of manufacturing the embedded flexible circuit board of FIG. 1.

FIG. 4 shows a cross sectional view of the first circuit substrate in FIG. 2 and the embedded middle body in FIG. 3 after fitting the embedded middle body onto the first circuit substrate.

FIG. 5 shows a cross sectional view of the structure in FIG. 4 after removing a base of the embedded middle body, as well as a cross sectional view of the embedded flexible circuit board manufactured through the method in FIG. 1.

FIG. 6 shows a cross sectional view of the structure in FIG. 5 after forming a second circuit substrate onto the first circuit substrate.

FIG. 7 shows a cross sectional view of the structure in FIG. 5 after fitting a single-sided substrate onto the first circuit substrate to form a middle structure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series and the like.

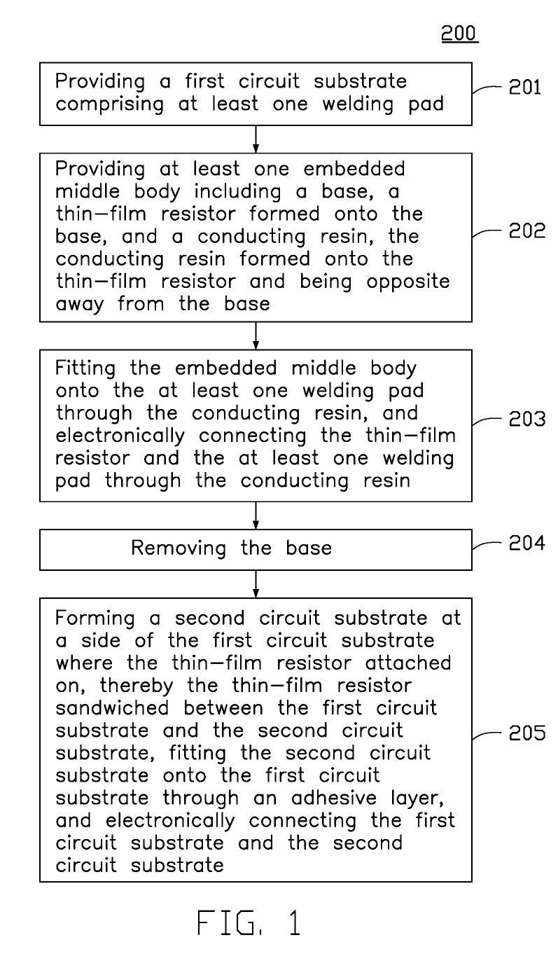

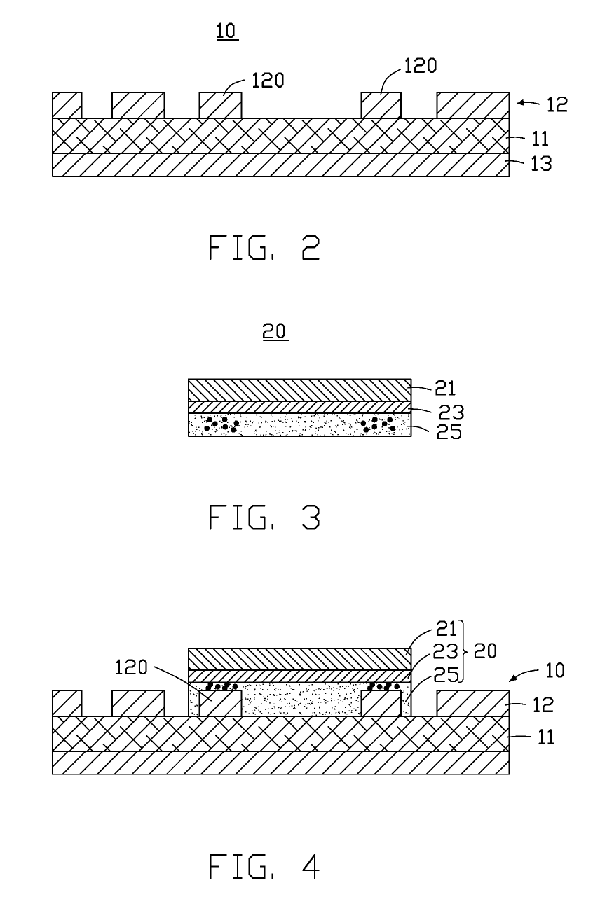

Referring to FIG. 1, FIG. 1 shows a flowchart for a method of manufacturing an embedded flexible circuit board 100 in accordance with an embodiment. The method 200 is provided by way of example, as there are a variety of ways to carry out the method. The method 200 described below can be carried out using the configurations illustrated in FIGS. 2 to 7, for example, and various elements of these figures are referenced in explaining the method 200. Each block shown in FIG. 1 represents one or more processes, methods, or subroutines, carried out in the method 200. Furthermore, the illustrated order of blocks is illustrative only and the order of the blocks can change. Additional blocks can be added or fewer blocks may be utilized, without departing from this disclosure. The example 200 can begin at block 201.

At block 201, providing a first circuit substrate 10 including at least one welding pad 120.

As illustrated in FIG. 2, the first circuit substrate 10 includes an insulated first basic layer 11 and a first pattern layer 12 formed onto the first basic layer 11, and the first pattern layer 12 includes the at least one welding pad 120.

Surface treatment may be carried on the welding pad 120, so that surface oxidation of the welding pad 120 would be avoided to retain electrical characteristics. Methods of surface treatment may be forming a protective layer (not shown in the figures) on the welding pad 120 through chemical gilding, electrolytic gilding, chemical tinning, or electrolytic tinning, or forming an organic solder-ability protection layer (OSP) on the welding pad 120. A number of the welding pad 120 may be changed actual needs.

In this embodiment, the first circuit substrate 10 is a double-sided panel. The first circuit substrate 10 further includes a conducting layer 13. The conducting layer 13 is formed onto the first basic layer 11 and is opposite from the first pattern layer 12. The conducting layer 13 is a copper foil layer or a pattern layer. In other embodiments, the first circuit substrate 10 may be a single-sided panel or a multilayer panel.

In this embodiment, the first circuit substrate 10 is made of, but not limited to, polyimide (PI), liquid crystal polymer (LCP), polyethylene terephthalate (PET), or Polyethylene Naphthalate (PEN).

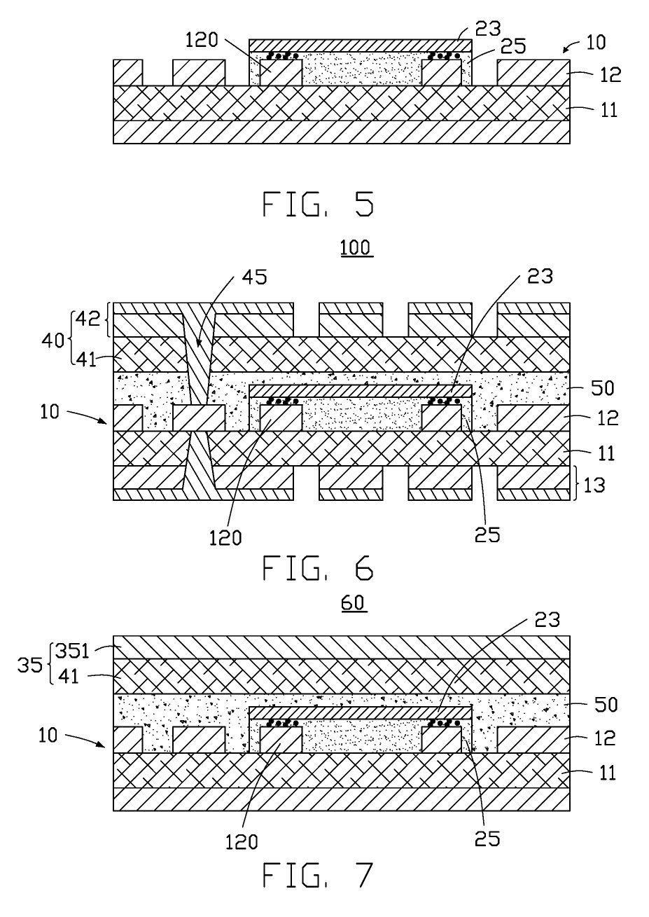

At block 202, as illustrated in FIG. 3, providing at least one embedded middle body 20 including a base 21, a thin-film resistor 23 formed onto the base 21, and a conducting resin 25, the conducting resin 25 formed onto the thin-film resistor 23 and being opposite from the base 21.

In this embodiment, the base 21 is a copper foil layer. A thickness of the thin-film resistor 23 is thinner than 1 μm.

In this embodiment, the conducting resin 25 is an anisotropic conductive adhesive.

At block 203, as shown in FIG. 4, fitting the embedded middle body 20 onto the at least one welding pad 120 through the conducting resin 25, and electronically connecting the thin-film resistor 23 and the welding pad 120 through the conducting resin 25.

The base 21 is used to increase a strength of the thin-film resistor 23 when the thin-film resistor 23 is attached onto the welding pad 120, to prevent the thin-film resistor 23 from being bent and deformed during the bonding.

At block 204, removing the base 21, as shown in FIG. 5.

In this embodiment, the base 21 is removed by way of etching.

At block 205, as shown in FIG. 6, forming a second circuit substrate 40 at a side of the first circuit substrate 10 where the thin-film resistor 23 attached on, thereby the thin-film resistor 23 sandwiched between the first circuit substrate 10 and the second circuit substrate 40, fitting the second circuit substrate 40 onto the first circuit substrate 10 through an adhesive layer 50, and electronically connected the first circuit substrate 10 and the second circuit substrate 40.

In this embodiment, the second circuit substrate 40 is a single-sided panel. The second circuit substrate 40 includes a second basic layer 41 and a second pattern layer 42 formed onto the second basic layer 41. The second basic layer 41 is fitted onto the first circuit substrate 10 through the adhesive layer 50. The second pattern layer 42 is electronically connected with the first circuit substrate 10 through at least one conducting structure 45. In other embodiments, the second circuit substrate 40 may be double-sided panel or a multilayer panel.

Specifically, referring to FIG. 6 and FIG. 7, after removing the base 21, a single-sided substrate 35 is attached onto the side of the first circuit substrate 10 where the thin-film resistor 23 is attached on. The single-sided substrate 35 and the structure after removing the base 21 together make up a middle structure 60. The single-sided substrate 35 includes an insulated second basic layer 41 attached onto the first circuit substrate 10 and a copper foil layer 351. The copper foil layer 351 is formed onto the second basic layer 41 and opposite from the first circuit substrate 10. The outermost copper foil layer 351 of the middle structure 60 is patterned to form the second circuit substrate 40, and the conducting structure 45 is further formed to electrically connect the second circuit substrate 40 and the first circuit substrate 10, thereby the embedded flexible circuit board 100 is fabricated.

In other embodiments, after removing the base 21, a completed second circuit substrate 40 may be fitted onto the first circuit substrate 10 through the adhesive layer 50, and the conducting structure 45 is further formed to electrically connect the second circuit substrate 40 and the first circuit substrate 10.

In this embodiment, the adhesive layer 50 is made of a viscous resin. The viscous resin may be at least one of Polypropylene, epoxy, polyurethane, phenolic, urea-formaldehyde, melamine-ormaldehyde and polyimide.

The upper manufacturing steps in blocks 202-205 may be repeated to add layers.

In FIG. 6, the embedded flexible circuit board 100 made by the method 200 described in the above embodiment includes a first circuit substrate 10 and a second circuit substrate 40. The second circuit substrate 40 is fitted onto the first circuit substrate 10 through an adhesive layer 50. The second circuit substrate 40 is electronically connected to the first circuit substrate 10. The first circuit substrate 10 includes at least one welding pad 120. The embedded flexible circuit board 100 further includes at least one thin-film resistor 23. The thin-film resistor 23 is embedded into the embedded flexible circuit board 100 and is sandwiched between the first circuit substrate 10 and the second circuit substrate 40. The thin-film resistor 23 is fitted on the welding pad 120 and electronically connected with the welding pad 120 through a conducting resin 25.

The first circuit substrate 10 includes a first basic layer 11 and a first pattern layer 12. The first basic layer 11 is insulated. The first pattern layer 12 is formed onto the first basic layer 11. The first pattern layer 12 includes the welding pad 120.

The second circuit substrate 40 includes a second basic layer 41 and a second pattern layer 42. The second basic layer 41 is insulated. The second pattern layer 42 is formed onto the second basic layer 41. The adhesive layer 50 bonds the first pattern layer 12 and the second basic layer 41.

A thickness of the thin-film resistor 23 is thinner than 1 μm.

In this embodiment, the conducting resin 25 is an anisotropic conductive adhesive. The embedded flexible circuit board 100 further includes at least one conducting structure 45. The conducting structure 45 electronically connects the first pattern layer 12 and the second pattern layer 42.

In the embodiment, the embedded flexible circuit board 100 further includes a conducting layer 13. The conducting layer 13 is formed onto the first basic layer 11 and is opposite from the first pattern layer 12. The conducting layer 13 is electronically connected with the first pattern layer 12.

Te method of manufacturing a embedded flexible circuit board 100 has simple manufacturing process, and does not need to form a resistance layer by an etching process, thereby avoiding large resistance value deviation caused by the etching process, so that the accuracy of manufacturing the embedded flexible circuit board 100 is improved, and the problem of excessive thickness of the circuit board caused by embedding elements is avoided.

The embodiments shown and described above are only examples. Many details are often found in the art such as the other features of manufacturing an embedded flexible circuit board. Therefore, many such details are neither shown nor described. Even though numerous characteristics and advantages of the present technology have been set forth in the foregoing description, together with details of the structure and function of the present disclosure, the disclosure is illustrative only, and changes may be made in the details, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

1. A method of manufacturing an embedded flexible circuit board, comprising:
providing a first circuit substrate comprising at least one welding pad;
providing at least one embedded middle body including a base, a thin-film resistor formed onto the base, and a conducting resin, the conducting resin formed onto the thin-film resistor and being opposite from the base;
fitting the embedded middle body onto the at least one welding pad through the conducting resin, and electronically connecting the thin-film resistor and the at least one welding pad through the conducting resin;
removing the base; and
forming a second circuit substrate at a side of the first circuit substrate where the thin-film resistor attached on, thereby the thin-film resistor sandwiched between the first circuit substrate and the second circuit substrate, fitting the second circuit substrate onto the first circuit substrate through an adhesive layer, and electronically connected the first circuit substrate and the second circuit substrate.

2. The method of manufacturing the embedded flexible circuit board of claim 1, wherein the conducting resin is an anisotropic conductive adhesive.

3. The method of manufacturing the embedded flexible circuit board of claim 1, wherein a thickness of the thin-film resistor is thinner than 1 μm.

4. The method of manufacturing the embedded flexible circuit board of claim 1, wherein the step of providing a first circuit substrate comprising at least one welding pad is further to carry on surface treatment on the at least one welding pad to form a protective layer.

5. The method of manufacturing the embedded flexible circuit board of claim 1, wherein the base is a copper foil layer.

6. The method of manufacturing the embedded flexible circuit board of claim 1, wherein the base is removed by way of etching.

7. An embedded flexible circuit board, comprising:
a first circuit substrate comprising at least one welding pad;
a second circuit substrate;
an adhesive layer fitting the second circuit substrate onto the first circuit substrate; and
at least one thin-film resistor embedded and sandwiched between the first circuit substrate and the second circuit substrate; and
wherein the at least one thin-film resistor is fitted on the at least one welding pad and electronically connected with the at least one welding pad through a conducting resin; the at least one welding pad comprises a protective layer formed thereon, the protective layer is located between the at least one welding pad and the conducting resin.

8. The embedded flexible circuit board of claim 7, wherein the conducting resin is an anisotropic conductive adhesive.

9. The embedded flexible circuit board of claim 7, wherein a thickness of the thin-film resistor is thinner than 1 μm.

10. (canceled)
